(19) United States
(12) Patent Application Publication
(10) Pub. No.: US 2003/0194845 A1
(43) Pub. Date: Oct. 16, 2003

(54) Method for fabricting a resistor on a printed circuit board

(75) Inventor: Wen-Long Jong, Taoyuan Hsien (TW)

Correspondence Address: Troxell Law Office PLLC, Suite 1404, 5205 Leesburg Pike, Falls Church, VA, 22041, US

(73) Assignee: COMPEQ MANUFACTURING COMPANY LIMITED

(21) Appl. No.: 10/119,214

(22) Filed: Apr. 10, 2002

(51) Int. Cl. H01L 21/8222

(52) U.S. Cl. 438/330; 438/382

(57) ABSTRACT

A method for fabricating a resistor on a printed circuit board (PCB) uses a resistance film material and a dry etching process to form a resistor on the PCB. The resistance film material has low dissolvent content to prevent the resistor from shrinking and affecting the resistance of the resistor. The resistance film material has a fixed thickness, so the thickness of the resistor in the PCB is easily controlled. Furthermore, the method uses a dry etching process to precisely form the resistor on the PCB to make the length and width of the resistor pattern very accurate.

### BACKGROUND OF THE INVENTION

1. Field of the Invention

The present invention relates to a method for fabricating a resistance on a printed circuit board (PCB), and more particularly to a method that provides accurate resistance of resistors on the PCB.

2. Description of Related Art

The earliest PCBs only had metallic lines to connect electronic components soldered on the PCB. Semiconductor technology has developed to the extent that some passive electronic components are directly formed on the PCB to reduce the space occupied by them and to reduce the radiation interference among the passive electronic devices such as resistors, capacitors, inductors etc. Therefore, PCB size can be reduced so PCBs can be used in very small electronic products.

Currently, conventional processes like the mesh printed method are available to form passive electronic components on PCBs. Fabricating a resistor on the PCB by the mesh printed method uses a stencil and a high resistance material to form a resistor on the PCB. The liquid resistor material can be a graphite or polyimide material or the like. Dissolvent in the graphite or polymide material is about 40% to 60%. The mesh printed method uses a steel plate with multiple holes or a steel stencil to form the resistor on the PCB.However, overflowing and deforming problems occur, which cause significant variations in the resistance of the resistor. For instance, the metallic lines first formed on the PCBare raised above the surface of the PCB. Gaps exist between the metallic lines and the printed circuit, so the liquid resistance material flows into the gaps to form the resistor. However, additional gaps are formed between the metallic lines and the surface of the PCB when the stencil is placed on the PCB, and additional liquid resistance material flows into these gaps causing the resistance of the individual resistors to vary widely because of this additional resistance material. Furthermore liquid resistance material sticks to the stencil further changing the resistance of the resistor after the stencil is removed from the PCB.

The mesh printed method using liquid resistance material to form resistors causes does not form a consistent resistor shape and has other features that affect the resistance of individual resistors. Consequently, the resistance of individual resistors varies by about 15% when the conventional mesh printed method is used.

Therefore, an objective of the present invention is to provide an improved method for fabricating resistors on PCBs to mitigate and/or obviate the aforementioned problems.

### SUMMARY OF THE INVENTION

The main objective of the present invention is to provide a method of fabricating resistors in a PCB with a consistent shape and resistance.

Other objects, advantages and novel features of the invention will become more apparent from the following detailed description when taken in conjunction with the accompanying drawings.

### BRIEF DESCRIPTION OF THE DRAWINGS

FIG. 1 is a flow chart of a method for fabricating a resistor on a printed circuit board (PCB) in accordance with the present invention;

FIGS. 2A to 2D are cross sectional side plan views of a first embodiment of a resistor formed by the method for fabricating a resistor on a printed circuit board (PCB) in accordance with the present invention; and

FIGS. 3A to 3C are cross sectional side plan views of a second embodiment of a resistor formed by a method for fabricating a resistor on a printed circuit board (PCB) in accordance with the present invention.

### DETAILED DESCRIPTION OF THE PREFERRED EMBODIMENT

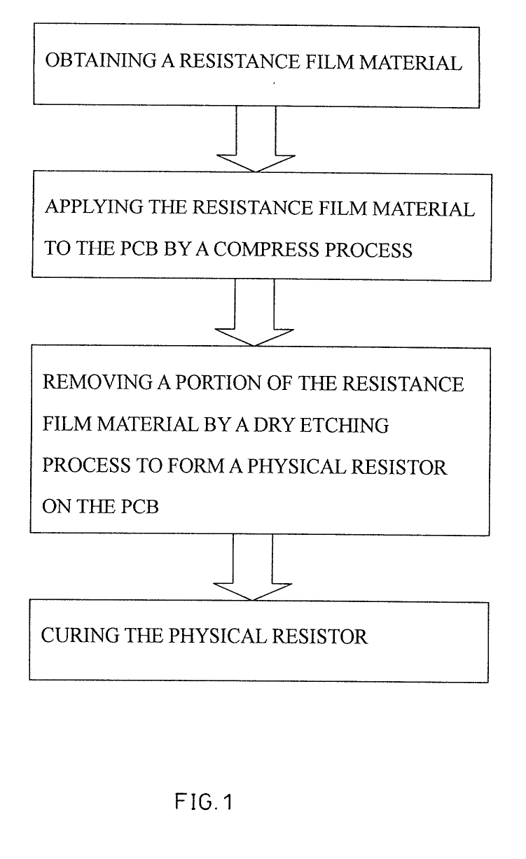

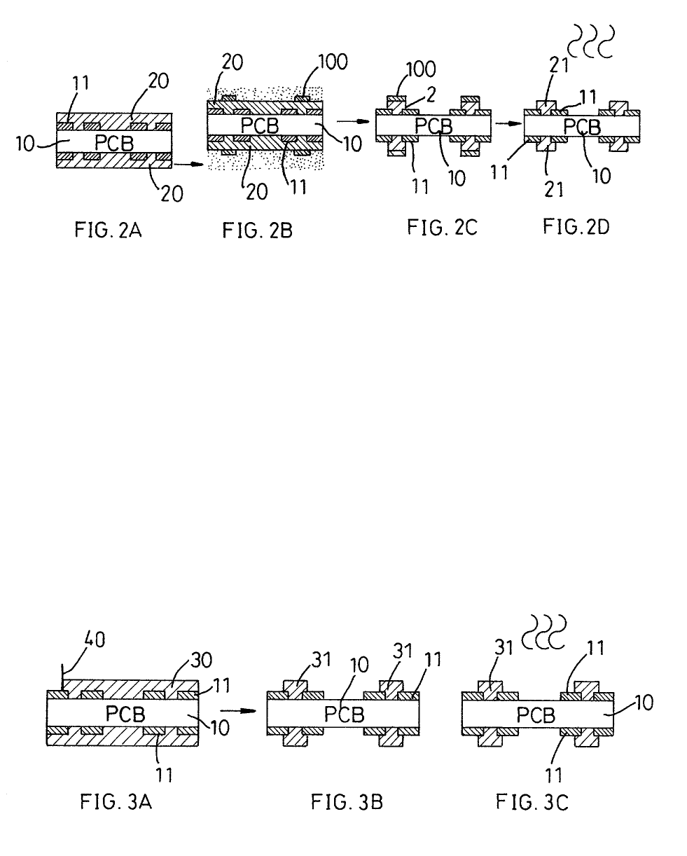

With reference to FIGS. 1 and 2, a method for fabricating a resistor (21) on a printed circuit board (PCB) (10) with two surfaces comprises steps of obtaining a resistance film material (20), applying the resistance film material (20) to at least one surface of the PCB (10) by a compress process, removing a portion of the resistance film material (20) by a dry etching process to form a physical resistor (21) on the PCB (10) and curing the physical resistor (21).

With reference to FIG. 2A, the resistance film material (20) is formed on the surface having the metallic lines (11). The applying the resistance film material (20) on the surface step uses the compress process such as vacuum compress process or wet compress with N-methyl-1-2-pyrrolidone (NMP).

With reference to FIG. 2B, a mask (100) with the resistor pattern is applied to the resistance film material (20). The resistance film material (20) not covered by the mask (20) chemically reacts with plasma ions or free radicals o. After the PCB (10) with the mask (100) is placed in a plasma etching room (not shown), the portion of the resistance film material (20) is removed.

With reference to FIG. 2C, the mask (100) still remains on the physical resistor (20) when the plasma etching process finished, so the mask (20) has to be removed to from the physical resistor (21). Finally, the physical resistor (21) is cured by a baking or UV light process to form the resistor on the PCB (10).

The resistance film material (20) used to fabricate resistors (21) on the PCB (10) has a fixed thickness, so the resistor (21) has is the same thickness. Because the method uses a plasma etching process, both length and width of the resistor are very accurate.

$$R = ( \frac{ρ}{t} ) \times \frac{L}{W}$$

The method fabricates the resistance of the resistor (21) on the PCB (11) very accurately based on the Resistance Rule shown.

Furthermore, the resistance film material (20) is a film, so the resistance film material (20) has a low quantity of the dissolvent (not shown). Therefore, the resistor (21) does not shrink during the curing step and cause the variation in the resistance of the resistor.

A second embodiment of the method for fabricating a resistor (21) on a printed circuit board (PCB) (10) with two surfaces by means of a dry etching process uses a laser beam to etch the resistance film material (20). A program is installed in a laser machine having a laser beam, which causes the laser beam to move according to a specify shape. With reference to FIG. 3A, the heat from the laser beam (40) removes the resistance film material (20). With reference to FIG. 3B, when the laser beam is finished, the physical resistor (31) is formed on the PCB (10). With reference to FIG. 3C, the physical resistor (31) is then cured by a baking or the UV light process.

The method for fabricating a resistor (21) on a printed circuit board (PCB) (10) in accordance with the present invention uses a resistance film material to exactly control the thickness of the resistor and ensure there is virtually no shrinkage during the curing process. Furthermore, a dry etching process is used to form the resistor pattern on the PCB so the shape of the resistor is also very accurate. Therefore, the thickness, the length and the width of the resistor pattern are very accurate, and the variation between resistors is very small.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for fabricating a resistor on a printed circuit board (PCB), wherein the PCB has the two surfaces, the method comprising steps of
obtaining a resistance film material;
applying the resistance film material on at least one surface of the PCB;
removing a portion of the resistance film material by a dry etching process to form a physical resistor on the PCB, wherein the portion of the resistance film material removed leaves a resistor pattern; and
curing the physical resistor.

2. The method as claimed in claim 1, wherein in the removing the portion of the resistance film material step, a plasma etching process removes the resistance film material not covered by a resistor pattern mask applied to the resistance film material, wherein the portion of resistance film material not covered by the resistor pattern mask chemically reacts with the plasma and is removed.

3. The method as claimed in claim 1, wherein in the removing the portion of the resistance film material step, laser beam removes a portion of the resistance film material to form the physical resistor on the PCB.

4. The method as claimed in claim 1, wherein the resistance film material is formed on the surface of the PCB by a compress process.

5. The method as claimed in claim 4, wherein the compress process is a vacuum compress process.

6. The method as claimed in claim 4, wherein the compress process is a wet compress process with N-methyl-2-pyrrolidone (NMP).

7. The method as claimed in claim 4, wherein curing the resistance pattern is performed by a baking process.

8. The method as claimed in claim 6, wherein curing the resistance pattern is performed by a baking process.

9. The method as claimed in claim 4, wherein curing the resistance pattern is performed by a UV process.

10. The method as claimed in claim 6, wherein curing the resistance pattern is performed by a UV process.
